(19) United States
(12) Patent Application Publication
(10) Pub. No.: US 2021/0293987 A1
(43) Pub. Date: Sep. 23, 2021

(54) EXPLORATION SYSTEM, MAGNETIC DETECTION APPARATUS, AND EXPLORATION METHOD

(71) Applicants: JAPAN OIL, GAS AND METALS NATIONAL CORPORATION, Tokyo (JP); SUPERCONDUCTING SENSOR TECHNOLOGY CORPORATION, Yokohama-shi (JP); MITSUI MINERAL DEVELOPMENT ENGINEERING CO., LTD., Tokyo (JP)

(72) Inventors: Hiroshi Chiba, Tokyo (JP); Hideaki Ban, Tokyo (JP); Yosuke Kunishi, Tokyo (JP)

(21) Appl. No.: 17/342,379

(22) Filed: Jun. 8, 2021

Related U.S. Application Data
(63) Continuation of application No. PCT/JP2019/045258, filed on Nov. 19, 2019.

(30) Foreign Application Priority Data
Dec. 26, 2018 (JP) 2018-243465

(51) Int. Cl. G01V 3/08; G01V 3/38

(52) U.S. Cl. CPC G01V 3/081; G01V 2003/084; G01V 3/083; G01V 3/38

(57) ABSTRACT

To provide an exploration system that electromagnetically explores a target structure, including: a magnetic field generation apparatus that generates a magnetic field toward the target structure; and a magnetic field detection apparatus that detects a magnetic field that propagates from the target structure, the propagated magnetic field being generated due to the magnetic field generated by the magnetic field generation apparatus, wherein the magnetic field detection apparatus has a communication part that transmits information of the detected magnetic field to an external device in synchronization with a timing at which the magnetic field generation apparatus generates the magnetic field and a timing at which the generation of the magnetic field is stopped.

### CROSS-REFERENCE TO RELATED APPLICATIONS

The present application is a continuation application of International Application number PCT/JP2019/045258, filed on Nov. 19, 2019, which claims priority under 35 U.S.C § 119(a) to Japanese Patent Application No. 2018-243465, filed on Dec. 26, 2018. The contents of these applications are incorporated herein by reference in their entirety.

### BACKGROUND

For purposes of geological surveys, underground resource explorations, and the like, electromagnetic prospecting techniques which electromagnetically measure electrical physical properties of geological features are known. In such electromagnetic prospecting techniques, a method of generating a periodically-changing primary magnetic field from a ground surface toward an exploration target, which is located underground, and detecting a secondary magnetic field generated by the primary magnetic field is known (see, for example, Patent Document 1, Japanese Unexamined Patent Application Publication No. 2009-79932, Patent Document 2, and Japanese Unexamined Patent Application Publication No. 2014-238275).

In such prospecting techniques, the secondary magnetic field that propagates from the exploration target becomes weak when the exploration target is more than a few hundred meters away from the ground. Therefore, the secondary magnetic field is detected by conducting processing such as averaging. In this case, the exploration is continued while monitoring a detection state, a detection result, and the like of the secondary magnetic field because the exploration time may take as long as several hours. When the detection result is transmitted from a detection apparatus during the detection of the secondary magnetic field to another apparatus, noise caused by the transmission operation is superimposed on the sensor output, and therefore detection accuracy may be reduced.

### SUMMARY

The present disclosure focuses on these points, and its object is to enable at least some of the detection result of the magnetic field to be transmitted to an external device during an exploration of a target structure while preventing a reduction of detection accuracy of the magnetic field.

A first aspect of the present disclosure provides an exploration system that electromagnetically explores a target structure, including: a magnetic field generation apparatus that generates a magnetic field toward the target structure; and a magnetic field detection apparatus that detects a magnetic field that propagated from the target structure, the propagated magnetic field being generated due to the magnetic field generated by the magnetic field generation apparatus, wherein the magnetic field detection apparatus has a communication part that transmits information of the detected magnetic field to an external device in synchronization with a timing at which the magnetic field generation apparatus generates the magnetic field and a timing at which the generation of the magnetic field is stopped.

A second aspect of the disclosure provides an exploration method that electromagnetically explores a target structure, including: generating a magnetic field toward the target structure with a magnetic field generation apparatus; detecting a magnetic field that propagated from the target structure, the propagated magnetic field being generated due to the magnetic field generated by the magnetic field generation apparatus; and transmitting information of the detected magnetic field to an external device in synchronization with a timing at which the magnetic field generation apparatus generates the magnetic field and a timing at which the generation of the magnetic field is stopped.

A third aspect of the present disclosure provides a magnetic detection apparatus having: an acquisition part that acquires time information; a magnetic sensor part that detects a magnetic field that propagated from the target structure, the propagated magnetic field being generated due to the magnetic field generated by the magnetic field generation apparatus; and a communication part that transmits information of the magnetic field detected by the magnetic sensor part to an external device in synchronization with the time information acquired by the acquisition part.

### BRIEF DESCRIPTION OF THE DRAWINGS

FIG. 1 shows a configuration example of an exploration system 10 according to the present embodiment.

FIG. 2 shows a configuration example of a magnetic field generation apparatus 100 according to the present embodiment.

FIG. 3 shows a configuration example of a switching part 160 according to the present embodiment.

FIG. 4 shows an example of a control signal with which a first control part 140 according to the present embodiment switches a state of the switching part 160.

FIG. 5 shows a configuration example of a magnetic field detection apparatus 200 according to the present embodiment.

FIG. 6 shows an example of a timing chart of the magnetic field generation apparatus 100 and the magnetic field detection apparatus 200 according to the present embodiment.

FIG. 7 shows a configuration example of a second control part 250 according to the present embodiment.

FIG. 8 shows a variation example of the timing chart of the magnetic field generation apparatus 100 and the magnetic field detection apparatus 200 according to the present embodiment.

FIG. 9 shows a second example of the second control part 250 according to the present embodiment.

FIG. 10 shows a third example of the second control part 250 according to the present embodiment.

### DETAILED DESCRIPTION OF THE INVENTION

Hereinafter, the present disclosure will be described through exemplary embodiments of the present disclosure, but the following exemplary embodiments do not limit the disclosure according to the claims, and not all of the combinations of features described in the exemplary embodiments are necessarily essential to the solution means of the disclosure.

### <Configuration Example of an Exploration System 10>

Electromagnetic prospecting techniques have been put into practical use for geological surveys and exploration of underground resources. An exploration system using the electromagnetic prospecting techniques generates a time-varying primary magnetic field and supplies it from a ground surface toward a target structure to be explored, which is located underground, for example. When the primary magnetic field varies over time, an induced current is generated in a direction for preventing the variation. The induced current generated in such a manner attenuates in accordance with the magnitude of the resistivity of geological features present in a propagation path. Then, a new induced current is generated in a direction for preventing time variation of the induced current due to the attenuation.

The induced current generated in such a process attenuates in accordance with the resistivity in the propagation path. In addition, the induced current diffuses three-dimensionally toward the depth direction over time. Here, for example, when a constant current for generating the primary magnetic field is instantaneously cut off, a diffusion depth δ which is the depth of the induced current diffusing in the depth direction can be expressed as δ=(2t/σμ)/2 (σ: conductivity of the underground, μ: permeability of the underground), using t as an elapsed time after cutting off the current. Therefore, the exploration system can obtain a resistivity distribution of the underground geological features by detecting the secondary magnetic field generated with the attenuation of the primary magnetic field, as a function of time. Also, the exploration system can obtain the resistivity distribution to greater depths by making the detection time longer. The exploration system can calculate a cross-sectional view of the resistivity distribution leading to the target structure to be explored, which is located underground, for example.

Conventionally, as a detection apparatus for detecting such a minute secondary magnetic field, it is known to use an induction-coil magnetometer, a superconducting quantum interference device (SQUID), or the like. In particular, since the SQUID can detect a more minute magnetic field, it can obtain the resistivity distribution of the target structure for geothermal, oil, natural gas exploration, etc., in deep underground or for metallic structure detection under the water in the distance. Therefore, in the present embodiment, examples in which such a SQUID is used as the detection apparatus will be described.

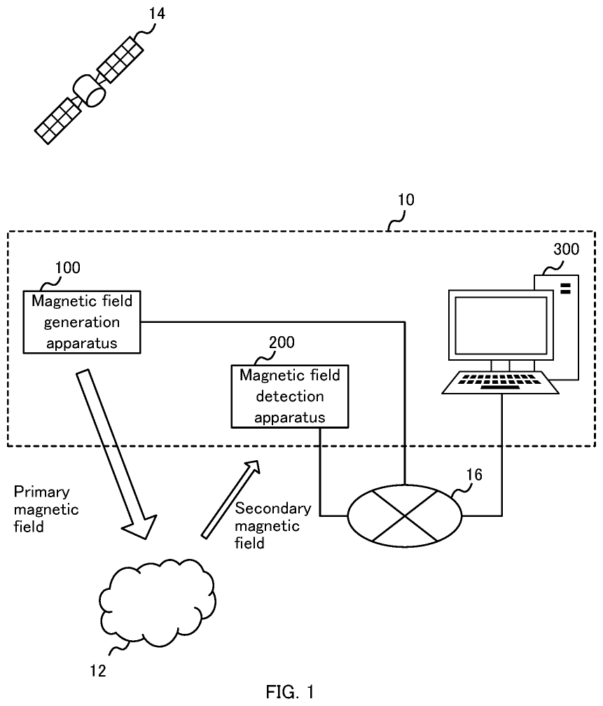

FIG. 1 shows a configuration example of an exploration system 10 according to the present embodiment. The exploration system 10 is an example of a system for electromagnetically exploring a target structure 12, as described above. For example, the target structure 12 is a region that includes or may include strata, minerals, oil, groundwater, or the like, which are to be explored and located underground. The exploration system 10 includes a magnetic field generation apparatus 100, a magnetic field detection apparatus 200, and a monitor device 300.

The magnetic field generation apparatus 100 generates a magnetic field toward the target structure 12. The magnetic field generation apparatus 100 is capable of controlling the generation of a magnetic field and the stopping of the generated magnetic field, and generates a time-varying magnetic field. The magnetic field generation apparatus 100 adjusts, on the basis of a timing signal received from an external device, a timing at which the magnetic field is generated, and a timing at which the generated magnetic field is stopped. FIG. 1 shows an example in which the magnetic field generation apparatus 100 receives a time signal from a satellite 14 such as a global positioning system (GPS) or the like and generates the magnetic field on the basis of the received time signal.

The magnetic field detection apparatus 200 detects, on the basis of the magnetic field generated by the magnetic field generation apparatus 100, the magnetic field propagated from the target structure 12. The magnetic field detection apparatus 200 is disposed at a distance several tens of meters to several thousand meters from the magnetic field generation apparatus 100 and transmits a detection result of the secondary magnetic field from the target structure 12 to the monitor device 300. The magnetic field detection apparatus 200 adjusts, on the basis of a timing signal received from an external device, a timing of detecting the secondary magnetic field from the target structure 12 and a timing of transmitting the detection result. FIG. 1 shows an example in which the magnetic field generation apparatus 100 and the magnetic field detection apparatus 200 operate in synchronization by having the magnetic field detection apparatus 200 receive the time signal from the satellite 14 such as the GPS, detect the detection result on the basis of the received time signal, and transmit the detection result to the secondary magnetic field. The example in which one magnetic field detection apparatus 200 detects the secondary magnetic field is shown in FIG. 1, for simplicity of explanation, but it is not limited to this. A plurality of magnetic field detection apparatuses 200 may detect the secondary magnetic field in synchronization.

The monitor device 300 is wired or wirelessly connected to the magnetic field detection apparatus 200 and receives the detection result of the secondary magnetic field. The monitor device 300 stores the detection result of the secondary magnetic field received from the magnetic field detection apparatus 200. Further, the monitor device 300 displays the detection result of the secondary magnetic field on a display unit or the like. Thus, an operator or the like of the monitor device 300 can confirm whether the operation of the magnetic field detection apparatus 200 is normal or not. The monitor device 300 may analyze the detection result of the secondary magnetic field to calculate the resistivity distribution or the like of the target structure 12. It should be noted that the magnetic field detection apparatus 200 may executes such an analysis and transmit an analysis result to the monitor device 300.

The monitor device 300 may also be wired or wirelessly connected to the magnetic field generation apparatus 100. In this case, the monitor device 300 can instruct the magnetic field generation apparatus 100 to confirm the operation, execute the operation, and the like. FIG. 1 shows an example in which the magnetic field generation apparatus 100, the magnetic field detection apparatus 200, and the monitor device 300 are connected to each other via a network 16. The network 16 may be the Internet, a local area network, or the like. In addition, the monitor device 300 may notify, via the network 16, another device such as a server or the like about the detection result of the secondary magnetic field or the like.

The example in which the exploration system 10 includes the magnetic field generation apparatus 100, the magnetic field detection apparatus 200, and the monitor device 300 is shown in FIG. 1, but it is not limited to this. The exploration system 10 may include the magnetic field generation apparatus 100 and the magnetic field detection apparatus 200. In this case, the exploration system 10 may transmit the detection result of the secondary magnetic field or the analysis result of the secondary magnetic field to an external device or the like, or instead, may accumulate the detection results of the secondary magnetic field or the analysis results of the secondary magnetic field.

As described above, the exploration system 10 detects the secondary magnetic field from the target structure 12 and transmits the detection result to the monitor device 300 for display. Here, if the target structure 12 is more than a few hundred meters away from the ground, the secondary magnetic field to be detected becomes a weak magnetic field on the order of picoteslas (pT). Therefore, in the magnetic field detection apparatus 200, the noise superimposed on the detection result was reduced by averaging results of detections performed a plurality of times. However, such a process prolongs the exploration time, and several hours may have passed before the exploration of the target structure 12 is completed. If the exploration time is prolonged in this manner, unless the operating state of the exploration system 10 is confirmed during the exploration, it would take several hours to find out about a problem, if it occurs.

Therefore, it is conceivable to monitor the detection state of the magnetic field by transmitting the detected data of the secondary magnetic field from the magnetic field detection apparatus 200 to the monitor device 300 during the exploration of the target structure 12. However, the magnetic field detection apparatus 200 that detects a weak magnetic field using the SQUID or the like may be affected by radio waves generated in the transmission operation of the data, and its detection accuracy may be reduced. For example, an electromagnetic wave may become noise and be superimposed on a magnetic field detection signal during data transmission via wireless communication such as Wi-Fi (registered trademark). Also, electromagnetic noise, generated by electrically switching a light source, may be superimposed on the magnetic field detection signal via a power supply line when data transmission via optical fibers or the like is used.

Therefore, in the exploration system 10 according to the present embodiment, the magnetic field detection apparatus 200 transmits at least some of the detection results of the magnetic field, the operation state, and/or the like to the monitor device 300 during the exploration of the target structure 12 while preventing the reduction of detection accuracy of the magnetic field. Such a magnetic field generation apparatus 100 and the magnetic field detection apparatus 200 will be described below.

### <Configuration Example of the Magnetic Field Generation Apparatus 100>

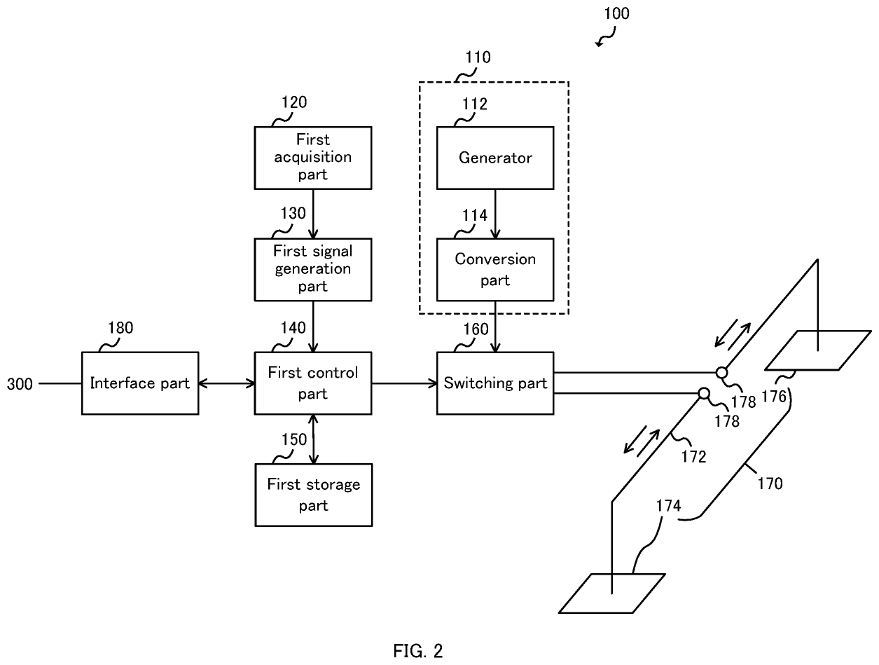

FIG. 2 shows a configuration example of the magnetic field generation apparatus 100 according to the present embodiment. The magnetic field generation apparatus 100 includes a current generation part 110, a first acquisition part 120, a first signal generation part 130, a first control part 140, a first storage part 150, a switching part 160, a magnetic field generation part 170, and an interface part 180.

The current generation part 110 generates DC current. The current generation part 110 generates a DC current of several tens of amperes to 100 amperes or more, for example. The current generation part 110 includes a generator 112 and a conversion part 114. The generator 112 is a three-phase AC alternator driven by a diesel engine or the like, for example. The conversion part 114 converts an AC current output by the generator 112 into a direct current which is approximately constant. The conversion part 114 includes a matrix converter, a switching regulator, or the like, for example.

The first acquisition part 120 acquires first time information. The first acquisition part 120 acquires the first time information from the satellite 14 of a global navigation satellite system (GNSS) such as GPS, for example. The first acquisition part 120 has an antenna and receives a signal that includes time information from an external device, for example. Further, the first acquisition part 120 may include a receiving circuit that removes noise components from the received signal and amplifies the signal component. Also, the receiving circuit may include a conversion circuit that converts frequency using a local oscillator, a mixer, or the like. The first acquisition part 120 supplies the acquired first time information to the first signal generation part 130.

The first signal generation part 130 generates a timing signal based on the first time information. The timing signal is a clock signal synchronized with the first time information, for example. The first signal generation part 130 supplies the generated timing signal to the first control part 140.

The first control part 140 performs control to switch whether or not to supply the current, which is generated by the current generation part 110, to the magnetic field generation part 170, on the basis of the timing signal. The first control part 140 is synchronized with the timing signal, and supplies, to the switching part 160, a control signal for controlling a switching operation of the switching part 160. That is, the first control part 140 controls the switching timing of the switching part 160 on the basis of the first time information acquired by the first acquisition part 120.

The first control part 140 may perform control to switch a direction of flow of the current generated by the current generation part 110. The first control part 140 may perform control to initialize the switching part 160. Further, the first control part 140 may cause the first storage part 150 to store (i) a switching state or the like of the switching part 160 and (ii) the time of switching, in association with each other. Also, the first control part 140 is connected to the current generation part 110, the first acquisition part 120, the first signal generation part 130, and the like, and may perform control to execute starting, stopping, resetting, or the like of the operation of each part.

The first storage part 150 stores the switching state and the like of the switching part 160. Further, the first storage part 150 may store switching patterns, an initial value, or the like of the switching part 160. In this case, the first control part 140 reads the switching patterns or the like stored in the first storage part 150, and generates the control signal to be supplied to the switching part 160, for example. Further, the first storage part 150 may store the operation state or the like of each part controlled by the first control part 140. Further, the first storage part 150 may store intermediate data, calculation results, thresholds, parameters, and the like, which are generated or used in an operation process of the magnetic field generation apparatus 100. Further, in response to a request from each part of the exploration system 10, the first storage part 150 may provide the stored data to a request source.

In response to the control signal received from the first control part 140, the switching part 160 switches whether or not to supply the current generated by the current generation part 110 to the magnetic field generation part 170. Also, the switching part 160 may further switch a direction of the current supplied to the magnetic field generation part 170 in response to the control signal. The switching operation of the switching part 160 will be described below.

The magnetic field generation part 170 generates a magnetic field on the basis of the current generated by the current generation part 110. The magnetic field generation part 170 includes a line source, a loop coil, an induction coil, or the like, for example, and generates the magnetic field corresponding to the current supplied from the current generation part 110. FIG. 2 shows an example in which the magnetic field generation part 170 includes the line source. The line source includes a cable 172, a first electrode 174, a second electrode 176, and power supply terminals 178.

The cable 172 has a length of several hundred meters to several kilometers, and is arranged to extend in one direction on the ground. The cable 172 has a length of, for example, about 800 meters to 2000 meters. At the ends of cable 172, the first electrode 174 and the second electrode 176 are respectively connected. Further, the cable 172 is cut at an approximately intermediate position, for example, and the power supply terminals 178 are respectively provided on two ends which are formed resulting from the cut. The two power supply terminals 178 are connected to the switching part 160. The cable 172 is, as an example, a stranded wire cable with a current capacity of 150 A.

The first electrode 174 and the second electrode 176 are buried at a distance of about 800 meters to 2000 meters apart from each other in the ground. Preferably, the first electrode 174 and the second electrode 176 are electrode plates having a larger area, and they each have a plurality of electrode plates, for example. As an example, the first electrode 174 and the second electrode 176 each have 10 sheets of galvanized iron, such as 600×1800 mm galvanized steel sheets or the like. In this case, the first electrode 174 and the second electrode 176 each include a plurality of electrode plates which are buried at intervals of approximately 5 meters and approximately parallel to the ground surface in the ground at a depth of 2 meters. When the burying point is a fresh water region, it is preferable to spray ammonium sulfate fertilizer or the like, serving as a conductive material, on the burying point, and then bury the plurality of electrode plates.

The interface part 180 communicates with the outside of the magnetic field generation apparatus 100. The interface part 180 communicates with the monitor device 300 via a wireless LAN, an optical fiber, or the like, for example. In this case, the monitor device 300 may inquire the first control part 140 of the operation state of each part of the magnetic field generation apparatus 100, and the first control part 140 transmits information about each part's operation state to the monitor device 300 in response to the inquiry. In addition, the monitor device 300 may instruct the first control part 140 to start, stop, reset, or the like the operation of each part via the interface part 180. In this case, the first control part 140 controls each part according to the received instruction.

The magnetic field generation apparatus 100 according to the present embodiment described above can supply the primary magnetic field toward the target structure 12 present at approximately 2000 meters underground, for example. The switching part 160 that switches the generation of the magnetic field and the stop of the generation of such a magnetic field generation apparatus 100 will be described below.

### <Configuration Example of the Switching Part 160>

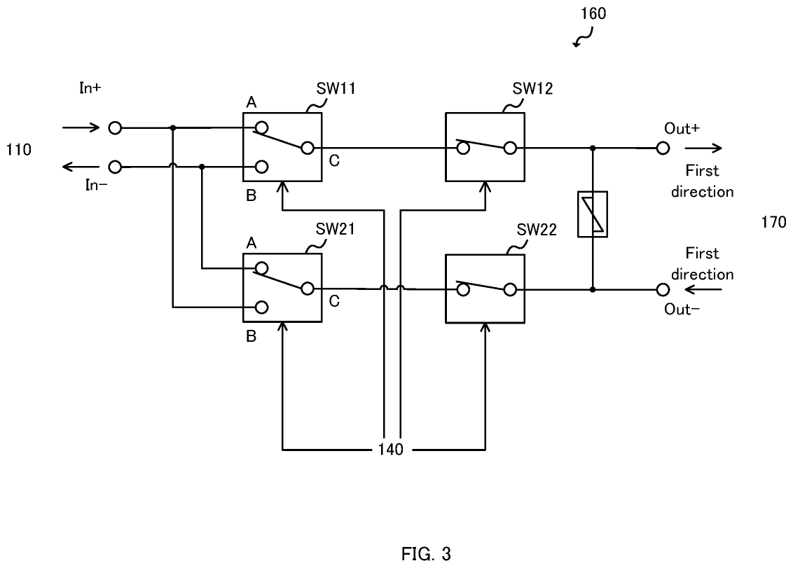

FIG. 3 shows a configuration example of the switching part 160 according to the present embodiment. FIG. 3 shows an example in which the switching part 160 switches whether to supply the current generated by the current generation part 110 to the magnetic field generation part 170, i.e. whether to switch to an energized state or a shut-off state. Also, when the current is supplied to the magnetic field generation part 170, the switching part 160 switches the current direction between the forward direction (first direction) and the reverse direction (second direction). That is, there are three states to be switched among by the switching part 160: a first-direction-energized state, a second-direction-energized state, and a shut-off state. FIG. 3 shows an example in which the switching part 160 is in the first-direction energized state.

FIG. 3 shows an example in which the switching part 160 has four switches, which are a switch SW11, a switch SW12, a switch SW21, and a switch SW22. The switch SW11 and the switch SW21 are C-contact switches such as two-in-one-out or one-in-two-out switches, for example. In FIG. 3, an example is illustrated in which each of the switch SW11 and the switch SW21 electrically connects or disconnects between (i) either one of a terminal A and a terminal B and (ii) a common terminal C.

The switch SW12 and the switch SW22 are A-contact switches or B-contact switches, such as one-in-one-out switches, for example. Each switch includes at least one of a mechanical relay, a photo MOSFET, a SiC MOSFET, or an IGBT, for example.

In FIG. 3, a positive input terminal of the switching part 160 is In+, and a negative input terminal is In−. The input terminal In+ and the input terminal In− are connected to the current generation part 110. In FIG. 3, the direction of current supplied from the current generation part 110 is indicated by an arrow. Further, a positive output terminal of the switching part 160 is Out+, and a negative output terminal of the switching part 160 is Out−. The output terminal Out+ and the output terminal Out− are respectively connected to two power supply terminals 178 of the magnetic field generation part 170.

The direction of current in which the current outputs from the output terminal Out+ and the current inputs from the terminal Out− are the first direction, and a direction opposite to the first direction is the second direction. In FIG. 3, the direction of current in the first direction is indicated by an arrow. It should be noted that a varistor, a Zener diode, or the like for absorbing surges may be provided between the output terminal Out+ and the output terminal Out−.

The first control part 140 provides the control signal to the switches of such a switching part 160 and performs control to switch among the three states of the switching part 160, which are the first-direction-energized state, the second-direction-energized state, and the shut-off state. For example, the first control part 140 provides a control signal to turn off the switch SW12 and the switch SW22 to shut off the switching part 160. In this case, the switch SW11 and the switch SW21 may be switched to either the terminal A or the terminal B, and may be connected in their initial state. FIG. 3 shows an example in which the switch SW11 and the switch SW21 are set so that the terminal A and the terminal C are connected in the initial state of the switch SW11 and the switch SW21.

Also, the first control part 140 provides a control signal to turn on the switch SW12 and the switch SW22 to energize the switching part 160. Here, the first control part 140 supplies the control signal that connects each of the switch SW11 and the switch SW21 to the terminal A to put the switching part 160 in the first-direction-energized state (FIG. 3). Alternatively, the first control part 140 provides a control signal that connects each of the switch SW11 and the switch SW21 to terminal B to put the switching part 160 in the second-direction-energized state.

It should be noted that the first control part 140, when turning on or off the switch SW12 and the switch SW22, preferably performs control to switch on the two switches with a predetermined time difference therebetween. As an example, the first control part 140 turns on the switch SW12 approximately 10 milliseconds before turning on the switch SW22. The first control part 140 also turns off the switch SW12 approximately 10 milliseconds after turning off the switch SW22. By doing this, it is possible to clearly set each timing, since the time at which the current begins to flow is the time when the switch SW12 is turned on and the time at which the current flow is stopped is the time when the switch SW22 is turned off.

Similarly, it is preferable that the first control part 140 controls the switching operation of the switch SW11 and the switch SW21 after the switch SW12 is turned off. As an example, the first control part 140 switches the switch SW11 and the switch SW21 20 milliseconds after turning off the switch SW12. Specific examples of patterns of how the first control part 140 switches the states of the switching part 160 in the manner described above will be described below.

### <An Example of Switching Patterns of the Switching Part 160>

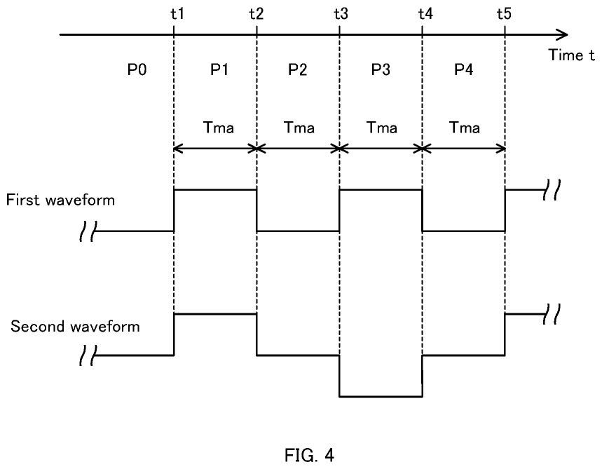

FIG. 4 shows an example of a control signal with which the first control part 140 according to the present embodiment switches the state of the switching part 160. In FIG. 4, the horizontal axis indicates the time and the vertical axis indicates the signal strength such as voltage. The first waveform of FIG. 4 shows a control signal with which the first control part 140 switches the switching part 160 to either an energized state or the shut-off state. As an example, the switching part 160 is in the energized state while the first waveform is in the high state, the switching part 160 is in the shut-off state while the first waveform is at the low state. The first control part 140 provides the control signal corresponding to the first waveform to the switch SW12 and the switch SW22.

Further, the second waveform of FIG. 4 indicates a control signal with which the first control part 140 switches the switching part 160 to one of the first-direction-energized state, the second-direction-energized state, and the shut-off state. As an example, the switching part 160 is in the first-direction-energized state while the second waveform is in the high state, the switching part 160 is in the shut-off state while the second waveform is in the middle state, and the switching part 160 is in the second-direction-energized state while the second waveform is in the low state. The first control part 140 provides the control signal corresponding to the second waveform to the switch SW11 and the switch SW21.

The first control part 140 puts the switching part 160 in the shut-off state in a period up to a time t1 with the control signal shown in FIG. 4, for example. Here, the period up to the time t1 is the 0th period P0 of a standby state or the initial state, and the first control part 140 switches the switch SW11 and the switch SW21 of the switching part 160 to the first-direction-energized state in this period.

Next, the first control part 140 operates the switches SW12 and SW22 to supply the current in the first direction from the switching part 160 to the magnetic field generation part 170 during a period from the time t1 to a time t2. Here, the period from the time t1 to the time t2 is referred to as a first period P1. Next, the first control part 140 operates the switches SW12 and SW22 to put the switching part 160 to the shut-off state at the time t2, and then switches the switches SW11 and SW21 of the switching part 160 to the second-direction-energized state during a period from the time t2 to a time t3. Here, the period from the time t2 to the time t3 is referred to as a second period P2.

Similarly, the first control part 140 operates the switches SW12 and SW22 of the switching part 160 to supply the current in the second direction from the switching part 160 to the magnetic field generation part 170 during the period from the time t3 to a time t4. Here, the period from the time t3 to the time t4 is referred to as a third period P3.

Next, the first control part 140 switches the switching part 160 to the shut-off state during a period from the time t4 to a time t5. Here, the period from the time t4 to the time t5 is referred to as a fourth period P4. By repeating the above operations, the switching part 160 supplies a rectangular current, whose polarity reverses alternately at the beginning of periods P1 and P3, to the magnetic field generation part 170. The P2 and P4, which are pause periods, are inserted before and after the periods P1 and P3. In response to this, the magnetic field generation part 170 generates a static magnetic field, whose polarity reverses alternately at the beginning of periods P1 and P3, before and after the pause periods P2 and P4.

The first period P1, the second period P2, the third period P3, and the fourth period P4 are preferably larger than a predetermined time interval Tdc. Here, the time interval Tdc is a time interval during which the secondary magnetic field generated on the basis of the generation and stop of the primary magnetic field propagates underground and becomes attenuated sufficiently below the detection limit to the extent that detection of the next secondary magnetic field will not be affected, for example.

The time interval Tdc is approximately 1 second to 3 seconds when the target structure 12 is less than 100 meters below the ground, for example. Further, when the purpose is to detect a contact interface of oil and water in water flooding in which the target structure 12 is an oil reservoir which is 2000 meters underground, the time interval Tdc is about 10 seconds, for example. The first period P1, the second period P2, the third period P3, and the fourth period P4 may be approximately the same time intervals, or may instead be different time intervals. FIG. 4 shows an example in which each period is approximately the same time interval Tma.

The first control part 140 repeats a cycle, which is a period from the first period P1 to the fourth period P4, for a predetermined number of times. That is, the first control part 140 controls the magnetic field generation part 170 to sequentially switch among four states of the switching part 160 at approximately constant time intervals. The four states of the switching part 160 are (i) the first period P1 in which the current is supplied in the first direction, (ii) the second period P2 in which the supply of the current in the first direction is stopped, (iii) the third period P3 in which the current is supplied in the second direction opposite to the first direction, and (iv) the fourth period P4 in which the supply of the current in the second direction is stopped.

In the magnetic field generation part 170, when current flows in one direction, polarization corresponding to the polarity of the current flowing may occur in the first electrode 174 and the second electrode 176, for example. When the current flows in the same direction each time the magnetic field generation part 170 generates a magnetic field, the magnitude of the generated magnetic fields may become unstable due to the accumulation of such polarization.

Therefore, the magnetic field generation apparatus 100 according to the present embodiment supplies, as shown by the second waveform of FIG. 4, current whose polarity is switched at constant intervals to the magnetic field generation part 170. In this manner, it is possible to reduce the occurrence of polarization in the magnetic field generation part 170. Further, for example, if an offset error of the approximately constant magnetic field has occurred, it is possible to reduce the offset error by canceling it by averaging the detection results for the magnetic fields in both directions, since the directions of generation of the magnetic fields of the magnetic field generation apparatus 100 change alternately.

It should be noted that current can be supplied even if the switches SW12 and SW22 are omitted. In the form of the magnetic field generation apparatus 100 of the present embodiment, the line source is cut off between the first electrode 174 and the second electrode 176 via the magnetic field generation part 170 using the switches SW12 and SW22 during the periods P2 and P4 in which current is not supplied to the magnetic field generation part 170. By doing this, it is possible to prevent an unintended magnetic field from being generated by electrical charge, which is generated by polarization during an energized period, flowing back through the line source of the magnetic field generation part 170. Further, since the magnetic field generation part 170 is insulated from the current generation part 110 in such a shut-off state, it is possible to prevent an electric shock or the like during a non-energized period.

The magnetic field generation apparatus 100 according to the present embodiment described above repeats the generation of the magnetic field and the stop of the generation of the magnetic field in a predetermined cycle while synchronizing with the first time information. The magnetic field detection apparatus 200 detects the secondary magnetic field propagated from the target structure 12 on the basis of the primary magnetic field generated by such a magnetic field generation apparatus 100. Such a magnetic field detection apparatus 200 will be described next.

### <Configuration Example of the Magnetic Field Detection Apparatus 200>

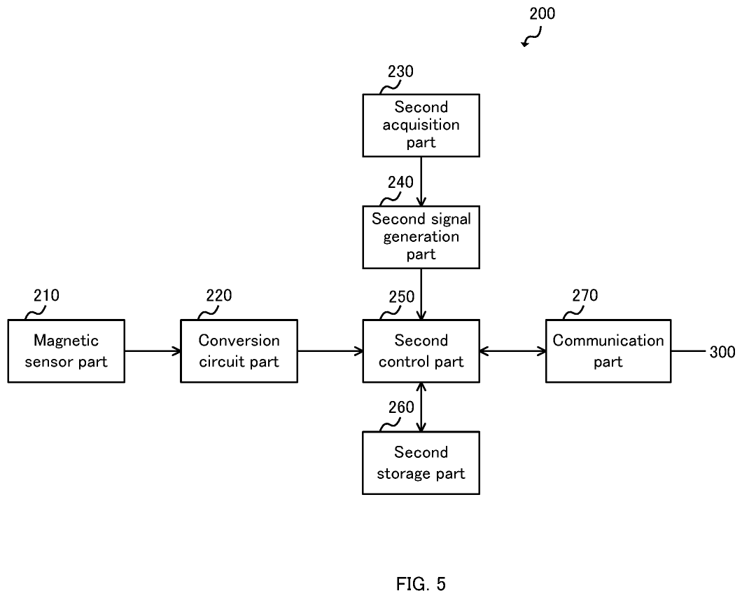

FIG. 5 shows a configuration example of the magnetic field detection apparatus 200 according to the present embodiment. The magnetic field detection apparatus 200 includes a magnetic sensor part 210, a conversion circuit part 220, a second acquisition part 230, a second signal generation part 240, a second control part 250, a second storage part 260, and a communication part 270.

The magnetic sensor part 210 detects the magnetic field propagated from the target structure 12. The magnetic sensor part 210 detects the secondary magnetic field propagated from the target structure 12 on the basis of the primary magnetic field magnetic field generated by the magnetic field generation apparatus 100. The magnetic sensor part 210 has the SQUID, for example, and outputs, as a detection signal, a voltage value corresponding to a magnetic flux to be input. In this case, the magnetic sensor part 210 further includes a cooling container that houses the SQUID, and a temperature sensor. The cooling container is a Dewar bottle, for example, that houses both the SQUID and the temperature sensor, and is filled with coolant such as liquid nitrogen. The temperature sensor is a platinum resistive sensor, as an example. The magnetic sensor part 210 may have a plurality of SQUIDs.

The conversion circuit part 220 converts the detection signal of the magnetic sensor part 210 to a digital signal. The conversion circuit part 220 includes a flux-locked loop (FLL) circuit and an A/D converter, for example. The FLL circuit outputs a voltage signal to make the SQUID work on the basis of a magnetic flux to be input to the SQUID and an output of the SQUID. The A/D converter converts the voltage signal output from the FLL circuit into a digital signal. Since the FLL circuit and the A/D converter are well known, a detailed description thereof is omitted here. Further, the conversion circuit part 220 may convert the detection signal of the temperature sensor into a digital signal. The conversion circuit part 220 supplies the converted digital signal to the second control part 250.

The second acquisition part 230 acquires second time information synchronized with the first time information acquired by the first acquisition part 120 of the magnetic field generation apparatus 100. Preferably, the second acquisition part 230 acquires the second time information from an acquisition source of the first time information acquired by the first acquisition part 120. The second acquisition part 230 acquires the second time information from the satellite 14, such as the GPS, and uses the acquired second time information to control internal timing of the magnetic field detection apparatus 200, for example. By doing this, the internal parts of the magnetic field generation apparatus 100 and the magnetic field detection apparatus 200 can be operated at synchronized timings. The second acquisition part 230 has an antenna and a receiving circuit, and receives a signal having time information from an external device, for example. The second acquisition part 230 supplies the acquired second time information to the second signal generation part 240.

The second signal generation part 240 generates a timing signal based on the second time information. As an example, the timing signal is a clock signal synchronized with the second time information. The second signal generation part 240 supplies the generated timing signal to the second control part 250.

The second control part 250 stores the digital signal received from the conversion circuit part 220 in the second storage part 260. The second control part 250 has a timer circuit driven by the clock signal, and stores, in the second storage part 260, the digital signal in association with time information generated by the timer circuit, for example. Further, the second control part 250 supplies, on the basis of the time information, the digital signal received from the conversion circuit part 220 to the communication part 270 and transmits the digital signal to an external device. For example, the second control part 250 transmits the digital signal to the external device at a timing based on a reference timing, which is based on a predetermined operation timing in the magnetic field generation apparatus 100.

The second storage part 260 stores information of the magnetic field detected by the magnetic sensor part 210 in association with the time information. The second storage part 260 may further store information concerning temperature detected by the temperature sensor. The second storage part 260 may store intermediate data, calculation results, thresholds, parameters, or the like, which are generated or used in the course of the operation of the magnetic field detection apparatus 200. Further, in response to a request from each part of the exploration system 10, the second storage part 260 may provide the stored data to a request source.

The communication part 270 communicates with the outside of the magnetic field detection apparatus 200. The communication part 270 communicates with the monitor device 300 via a wireless LAN, an optical fiber, or the like, for example. The communication part 270 transmits the information of the detected magnetic field to an external device at a timing based on the second time information. By doing this, the communication part 270 transmits the information of the detected magnetic field to the external device in synchronization with a timing at which the magnetic field generation apparatus 100 generates the magnetic field and a timing at which the generation of the magnetic field is stopped. The communication part 270 transmits the information of the magnetic field in response to the control signal received from the second control part 250. Also, the communication part 270 stops the transmission of the information of the magnetic field in response to the control signal. The transmission operation or the like of the communication part 270 will be described below.

In addition, the communication part 270 may transmit the information of the detected magnetic field, the operation state of each part, and the like in response to a request from the external device. In this case, the monitor device 300 may make an inquiry to the second control part 250 about the information of the magnetic field and the operational state of each part of the magnetic field detection apparatus 200, via the communication part 270. The second control part 250 transmits the requested information in response to the inquiry. Further, the monitor device 300 may instruct the second control part 250 to start, stop, reset, or the like the operation of each part via the communication part 270. In this case, the second control part 250 controls each part according to the received instruction. In this manner, the communication part 270 may function as an interface with an external device.

As described above, the exploration system 10 according to the present embodiment synchronizes the timing of the generation operation of the primary magnetic field of the magnetic field generation apparatus 100 and the timing of transmitting the detection result of the secondary magnetic field of the magnetic field detection apparatus 200 on the basis of the time information. Such a timing operation of the magnetic field generation apparatus 100 and the magnetic field detection apparatus 200 will be described below.

### <First Example of a Timing Chart>

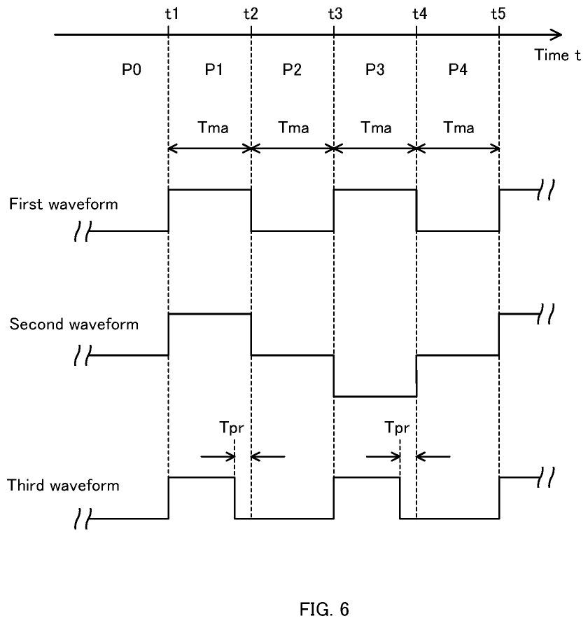

FIG. 6 shows an example of a timing chart of the magnetic field generation apparatus 100 and the magnetic field detection apparatus 200 according to the present embodiment. In FIG. 6, the horizontal axis indicates the time and the vertical axis indicates the amplitude intensity of the signal. A first waveform and a second waveform each show an example of a control signal supplied to the switching part 160 by the first control part 140 in the magnetic field generation apparatus 100. The descriptions of the first waveform and the second waveform are omitted here since they are approximately the same signal waveforms as in the example of the first waveform and the second waveform described in FIG. 4.

A third waveform shows an example of a control signal supplied to the communication part 270 by the second control part 250 in the magnetic field detection apparatus 200. In FIG. 6, a period in which the third waveform is in the high state is a period for transmitting the detection result of the secondary magnetic field to the communication part 270. Also, a period in which the third waveform is in the low state is a period in which the transmission of the detection result of the secondary magnetic field of the communication part 270 is stopped.

Here, the secondary magnetic field that propagates from the target structure 12 is generated in accordance with temporal variation of the primary magnetic field. Therefore, the secondary magnetic field is generated in response to the cutting off of the supply of the primary magnetic field to the target structure 12 of the magnetic field generation apparatus 100. For example, in FIG. 6, the secondary magnetic field to be used for an exploration of the target structure 12 propagates toward the magnetic field detection apparatus 200 after the first period P1 is switched to the second period P2. Similarly, the secondary magnetic field propagates toward the magnetic field detection apparatus 200 after the third period P3 is switched to the fourth period P4.

Therefore, the magnetic field detection apparatus 200 detects the propagated secondary magnetic field during the second period P2 and the fourth period P4. Thus, during a period in which at least the secondary magnetic field is propagating, such as the second period P2 and the fourth period P4, the magnetic field detection apparatus 200 operates independently of the detection operation of the magnetic field and stops at least some of the operation that would generate noise. As a result, the influence of noise generated inside the magnetic field detection apparatus 200 on the detection result of the secondary magnetic field can be reduced.

The second control part 250 stops a communication operation from the communication part 270 to an external device during a period when generation of the magnetic field by the magnetic field generation apparatus 100 is stopped, for example. In this case, the second control part 250 supplies, to the communication part 270, the third waveform which is in the low state during the second period P2 and the fourth period P4. Further, the second control part 250 supplies, to the communication part 270, the third waveform which is in the high state during the first period P1 and the third period P3, for example.

In this manner, the communication part 270 transmits the information of the detected magnetic field to the external device during the period when the magnetic field generation apparatus 100 is generating the magnetic field. Also, the communication part 270 stops transmitting the information of the detected magnetic field until a predetermined time passes from the reference timing at which the magnetic field generation apparatus 100 stops generating the magnetic field. FIG. 6 shows an example in which the communication operation of the communication part 270 is stopped until the magnetic field generation apparatus 100 generates the primary magnetic field next, in other words until the time interval Tma (>Tdc) from the reference timing has passed.

As described above, the communication part 270 stops the communication operation during the period in which the magnetic sensor part 210 detects the secondary magnetic field during the exploration of the target structure 12 of the exploration system 10. Therefore, the exploration system 10 of the present embodiment can transmit at least some of the detection result of the magnetic field to the external device during the exploration of the target structure 12 while preventing the reduction of detection accuracy of the magnetic field due to the communication operation of the communication part 270. Further, since the reduction of detection accuracy of the magnetic field due to the communication operation of the communication part 270 can be prevented, the overall size of the magnetic field detection apparatus 200 can be made compact by providing the communication part 270 near the conversion circuit part 220.

Also, the exploration system 10 detects the secondary magnetic field generated during a period in which the magnetic field generation apparatus 100 is stopping the generation of the primary magnetic field. Therefore, it is possible to prevent the noise components, such as ripples or the like that occur due to an operation of the conversion part 114 converting the AC current to the DC current, from being superimposed on the detection result of the magnetic sensor part 210, for example. The noise components occur as a result of the magnetic field generation apparatus 100 generating the primary magnetic field.

It should be noted that the first period P1, the second period P2, the third period P3, and the fourth period P4 are approximately the same time interval Tma, as shown in FIG. 6, and it is preferable to set the time interval Tma to integer multiples of a frequency period of a commercial AC power supply. In this manner, it is possible to reduce the noise components based on a commercial power supply frequency by canceling them by calculating a difference between the detection result of the secondary magnetic field of the second period P2 and the detection result of the secondary magnetic field of the fourth period P4.

Further, it is preferable that the second control part 250 stops the communication operation from the communication part 270 to the external device at a timing prior to the reference timing at which the magnetic field generation apparatus 100 stops generating the magnetic field. That is, the communication part 270 stops transmitting the information of the detected magnetic field at a timing prior to the timing at which the magnetic field generation apparatus 100 stops generating the magnetic field. FIG. 6 shows an example in which the communication part 270 stops the communication operation at a time which is earlier than the reference time by a predetermined time Tpr.

Here, the time Tpr is a time sufficient for the generation of noise due to the data transmission of the communication part 270 to converge and for the influence on the detection result of the magnetic sensor part 210 to be reduced. The time Tpr is about 0.02 seconds to 3 seconds, preferably about 0.06 seconds to 1 second, and more preferably about 0.1 seconds to 1 second, for example. A time interval during which the communication part 270 continues the data transmission is Tma−Tpr, and it is preferable that the time interval Tma−Tpr is a longer interval than the time interval Tdc. By doing this, the secondary magnetic field generated with the transition from the shut-off state to the energized state is attenuated sufficiently below the detection limit during the time-interval Tma−Tpr, and therefore it is possible to reduce the influence on the detection of the secondary magnetic field that will be generated next.

Also, it is preferable that the time Tpr is integer multiples of a frequency period of a commercial power supply frequency. In this case also, it is possible to reduce the noise components based on the commercial power supply frequency by canceling them by calculating a difference between (i) a detection result of the secondary magnetic field of a period including the second period P2 and (ii) a detection result of the secondary magnetic field of a period including the fourth period P4.

In FIG. 6, an example in which the communication part 270 starts the transmission of the information of the detected magnetic field at approximately the same timing that the magnetic field generation apparatus 100 starts the generation of the magnetic field is shown, but the communication part 270 is not limited to this. Alternatively, the communication part 270 may start the transmission of the information of the detected magnetic field after the timing at which the magnetic field generation apparatus 100 starts the generation of the magnetic field. Since the communication part 270 transmits the information of the detected magnetic field to the external device during a period that includes the first period P1 and the third period P3 in this manner, the communication part 270 can reduce the influence of noise components generated with the generation of the primary magnetic field.

In the above-described magnetic field detection apparatus 200, the magnetic sensor part 210 may continuously perform detection of the secondary magnetic field during the exploration of the target structure 12. In this case, the magnetic field detection apparatus 200 stores successive detection results of the secondary magnetic field during the exploration period in the second storage part 260. In this case, noise that occurs during the communication period of the communication part 270 is superimposed on the stored detected results, and long-period noise that occurs during the exploration period may also be superimposed on the stored detection results. The long-period noise is an error phenomenon or the like in magnetic field measurement, such as geomagnetic variation or fluctuation, slipping, or the like of the magnetic field caused by railway current, for example.

For example, the magnetic field detection apparatus 200 or the monitor device 300 may detect such long-period noise by analyzing the successive detection results of the secondary magnetic field during the exploration period. Therefore, since the magnetic field detection apparatus 200 or the monitor device 300 can remove long-period data from the detection results transmitted by the communication part 270, the magnetic field detection apparatus 200 or the monitor device 300 can obtain a more accurate detection result. Further, since the level of high-frequency noise is low during a shut-off period of the primary magnetic field, such as the second period P2 and the fourth period P4, the magnetic sensor part 210 can obtain more accurate detection results by suppressing the occurrence of slipping phenomenon.

In the above explanation, cases where the magnetic field generation apparatus 100 and the magnetic field detection apparatus 200 are synchronized by using the time information, and the exploration system 10 for performing the generation of the preliminary magnetic field, the detection of the secondary magnetic field based on the preliminary magnetic field, and the transmission of the detection result of the secondary magnetic field have been described. Additionally, the exploration system 10 may perform a predetermined operation at a predetermined time. For example, the first control part 140 controls the switching part 160 to, every hour on the hour, stop supplying current from the current generation part 110 to the magnetic field generation part 170. In this manner, since the exploration system 10 sets a timing for controlling the supply of the current to every hour on the hour, a timing design or the like can be easily performed.

Further, in this case, it is preferable to set a detection period 4·Tma, which is from the first period P1 to the fourth period P4, to a divisor of 3600 in unit of seconds, for example. By doing this, the reference timing or the like becomes a natural number in seconds, and it is possible to reduce processing for surplus time in the time calculation of the internal parts of the magnetic field generation apparatus 100 and the magnetic field detection apparatus 200. As an example, it is conceivable to set P1=P2=P3=P4=Tma=10 seconds, Tpr=0.1 seconds, or the like. A more specific configuration of the second control part 250 that controls the communication operation of the communication part 270 to have a timing as shown in FIG. 6 will be described below.

### <First Example of the Second Control Part 250>

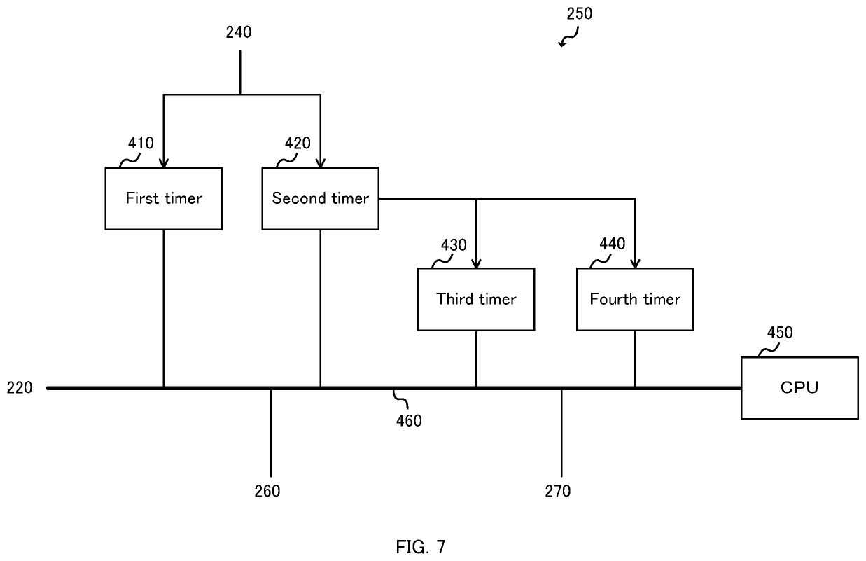

FIG. 7 shows a configuration example of the second control part 250 according to the present embodiment. The second control part 250 includes a first timer 410, a second timer 420, a third timer 430, a fourth timer 440, a CPU 450, and a bus 460. The first timer 410 to the fourth timer 440 each output a signal for notifying that a predetermined time has passed. The first timer 410 to the fourth timer 440 and the CPU 450 communicate with each other via the bus 460. The second control part 250 may also communicate with the conversion circuit part 220, the second storage part 260, and the communication part 270 via the bus 460.

The first timer 410 supplies, to the conversion circuit part 220, a first timer signal synchronized with the timing signal output by the second signal generation part 240. The first timer signal drives the A/D converter or the like of the conversion circuit part 220, for example. The second control part 250 may further include a DMA controller or the like driven by the first timer signal, and may read data from the A/D converter and transmit the data to the second storage part 260 or the like.

The second timer 420 generates a second timer signal synchronized with the reference timing at which the primary magnetic field detection apparatus 200 stops the generated primary magnetic field. That is, the reference timing is the transition from the first period P1 to the second period P2 and the transition from the third period P3 to the fourth period P4. The second timer 420 generates a second timer signal on the basis of (i) the timing signal output by the second signal generation part 240 every hour on the hour and (ii) the detection period 4·Tma, which is from the first period P1 to the fourth period P4, set in advance, for example. The second timer 420 supplies, to the third timer 430 and the fourth timer 440, the generated second timer signal as a timer start signal.

The third timer 430 generates a third timer signal synchronized with a timing which is a time 2Tma−Tpr later than the timing of receiving the second timer signal. The third timer 430 supplies, to the communication part 270, the generated third timer signal as a signal for notifying about the end of the data transmission.

The fourth timer 440 generates a fourth timer signal synchronized with a timing which is a time Tma later than the timing of receiving the second timer signal. The fourth timer 440 supplies, to the communication part 270, the generated fourth timer signal as a signal for notifying about the start of the data transmission.

As described above, the third timer 430 and the fourth timer 440 supply the signals that notify about the start of the data transmission and the end of the data transmission to the communication part 270, each time the third timer 430 and the fourth timer 440 receive the second timer signal from the second timer 420. Therefore, the communication part 270 can transmit the information of the detected magnetic field to the external device at approximately the same timing as in the timing chart shown in FIG. 6. Here, the third timer 430 and the fourth timer 440 may each be a timer with a lower accuracy than the accuracy of the second timer 420, since they are driven on the basis of the reference timing of the second timer 420.

For example, the third timer 430 and the fourth timer 440 may each be a timer driven by a system clock and implemented as application software to be operated on an OS. Also, the first timer 410 and the second timer 420 may be configured with a high-precision clock circuit or the like. The timing chart of the magnetic field generation apparatus 100 and the magnetic field detection apparatus 200 shown in FIG. 6 is an example, and the present embodiment is not limited to this. Therefore, timing charts different from the timing chart of FIG. 6 will be described below.

### <Second Example of the Timing Chart>

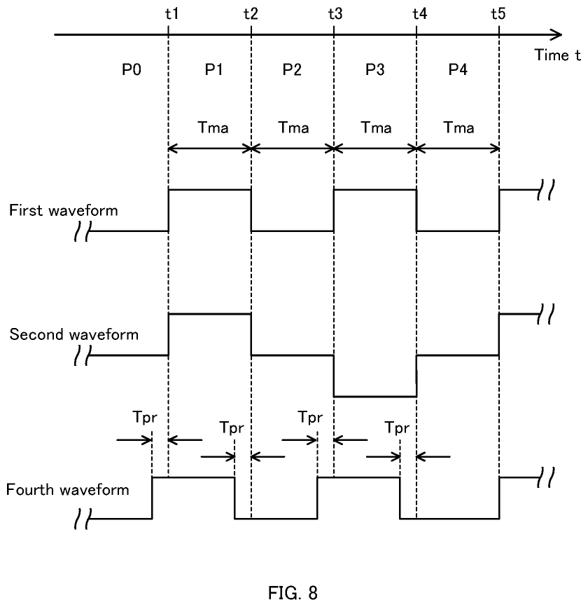

FIG. 8 shows a variation example of the timing chart of the magnetic field generation apparatus 100 and the magnetic field detection apparatus 200 according to the present embodiment. In FIG. 8, the horizontal axis indicates the time and the vertical axis indicates the amplitude intensity of the signal. The first waveform and the second waveform each show an example of a control signal supplied to the switching part 160 by the control part 140 in the magnetic field generation apparatus 100. The descriptions of the first waveform and the second waveform are omitted here since they are approximately the same signal waveforms as in the example of the first waveform and the second waveform described in FIG. 4.

A fourth waveform shows an example a control signal supplied to the communication part 270 by the second control part 250 in the magnetic field detection apparatus 200. In FIG. 8, a period in which the first waveform is in the high state is a period for transmitting the detection result of the secondary magnetic field to the communication part 270. Also, a period in which the third waveform is in the low state is a period in which the transmission of the detection result of the secondary magnetic field of the communication part 270 is stopped.

The fourth waveform is a signal obtained by shifting a signal phase of the first waveform so that a rise timing and a fall timing of the first waveform are earlier by a predetermined time Tpr. That is, when the magnetic field generation apparatus 100 repeats the generation of the primary magnetic field and the stop of the generation of the primary magnetic field in a predetermined cycle, the communication part 270 repeats the transmission of the information of the detected magnetic field in the same cycle as this cycle. In the timing chart of the variation example shown in FIG. 8, a communication starting timing of the communication part 270 is earlier than that of the timing chart shown in FIG. 6 by Tpr. Therefore, since the time interval at which the communication part 270 continues the data transmission becomes Tma−2Tpr, it is preferable that the time interval Tma−2Tpr is an interval that is longer than the time interval Tdc.

As an example, it is conceivable to set P1=P2=P3=P4=Tma=15 seconds, Tpr=0.1 seconds, or the like. The second control part 250 shown in FIG. 7 may also control the communication operation of the communication part 270 at the timing shown in FIG. 8, but it is not limited to this. A simpler configuration of the second control part 250 will be described below.

### <Second Example of the Second Control Part 250>

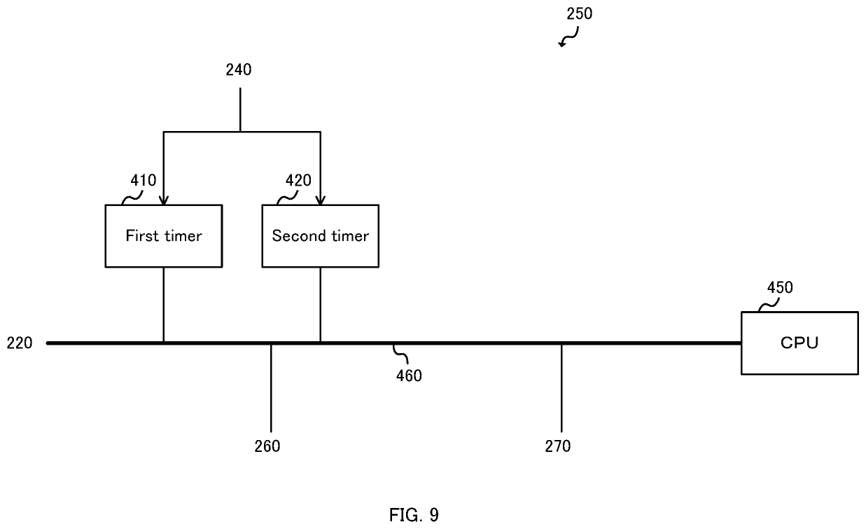

FIG. 9 shows a second example of the second control part 250 according to the present embodiment. In the second control part 250 of the second embodiment shown in FIG. 9, approximately the same operations as those of the second control part 250 shown in FIG. 7 are denoted by the same reference numerals, and descriptions thereof are omitted. The second control part 250 of the second example has a configuration in which the third timer 430 and the fourth timer 440 are omitted.

The second timer 420 generates a second timer signal synchronized with a timing which is earlier by Tpr than the reference timing at which the primary magnetic field detection apparatus 200 stops the generated primary magnetic field. The second timer 420 can generate such a second timer signal on the basis of (i) the timing signal output by the second signal generation part 240 every hour on the hour and (ii) the detection period 4·Tma, which is from the first period P1 to the fourth period P4, set in advance. Then, the second timer 420 supplies, to the communication part 270, the generated second timer signal as a signal for notifying about the start of the data transmission and the end of the data transmission. As a result, the communication part 270 can transmit the information of the detected magnetic field to the external device at approximately the same timing as in the timing chart shown in FIG. 8.

Cases where the above described second control part 250 according to the present embodiment uses the timers to generate the timing signals which instruct the start and end of the communication of the communication part 270 have been described, but the present disclosure is not limited to this. The second control part 250 may generate such timing signals using a counter or the like. Such a second control part 250 will be described below.

### <Third Example of the Second Control Part 250>

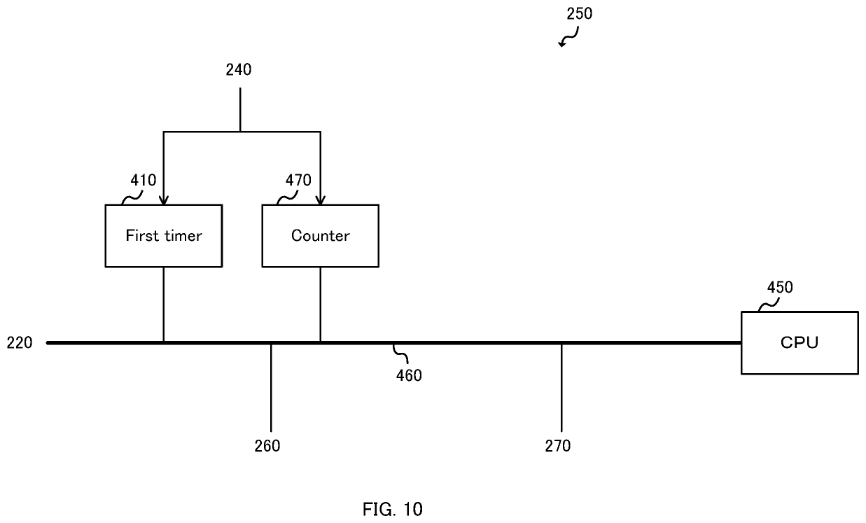

FIG. 10 shows a third example of the second control part 250 according to the present embodiment. In the second control part 250 of the third embodiment shown in FIG. 10, approximately the same operations as those of the second control part 250 shown in FIG. 7 are denoted by the same reference numerals, and descriptions thereof are omitted. The second control part 250 of the third example has a counter 470 instead of the three timers that are the second timer 420 to the fourth timer 440.

The counter 470 counts the timing signal from the second signal generation part 240 and acquires an elapsed time from the reference timing. The counter 470 counts the timing signal at every timing when 1 second passes from on-the-hour to acquire an elapsed time telp in seconds, for example. Here, telp may be an integer from 0 to 3599.

For example, in the timing chart shown in FIG. 6, when on-the-hour is the reference timing, the communication part 270 starts the transmission at the timing when (2k−1)·Tma passed from on-the-hour, and ends the transmission at the timing when 2·(2k−1)·Tma−Tpr passed. Here, k is a natural number of 1 or more. That is, when the count of the counter 470 corresponds to a period between (2k−1)·Tma 2 and 2·(2k−1)·Tma−Tpr, the second control part 250 controls the communication part 270 to be in the data-transmission period.

For example, the counter 470 divides the elapsed time telp by 2·Tma, which is a cycle of the data transmission and suspension of the communication part 270, and supplies, to the communication part 270, a timing signal for notifying about the start of the communication when modulo telp(mod 2·Tma) becomes Tma. Also, the counter 470 supplies, to the communication part 270, a timing signal for notifying about the end of the communication when the modulo telp(mod 2·Tma) becomes 2·Tma−Tpr. By doing this, the communication part 270 operates in a similar manner as in the communication part 270 of the timing chart shown in FIG. 6. As described above, the second control part 250 may generate the timing signals which instruct the start and end of the communication of the communication part 270 by using the counter or the like.

According to the exploration system 10 of the present exemplary embodiment, even when the target structure 12 to be explored is located underground at a distance of several hundred meters or more from the ground and the exploration time may take several hours, the exploration state or the like of the exploration system 10 can be monitored while preventing the reduction of detection accuracy. Cases where the noise superimposed on the detection result of the magnetic sensor part 210 is reduced by controlling the start and end of communication of the communication part 270 have been described as examples, but the present embodiment is not limited thereto.

For example, when a rechargeable battery is used in the exploration system 10, a charging power supply for charging the rechargeable battery may generate switching noise or the like. In this case, an operation of the charging power supply may be controlled to synchronize with the timings at which the magnetic field generation apparatus 100 generates the magnetic field and stops the generation of the magnetic field. By doing this, even when the rechargeable battery is charged during the exploration of the target structure 12, noise superimposed on the detection result of the magnetic sensor part 210 can be reduced.

Similarly, even when the exploration system 10 includes a motor for a refrigerator that produces refrigerant to be used for cooling the magnetic sensor part 210, an operation of this motor for the refrigerator may be controlled to synchronize with the timings at which the magnetic field generation apparatus 100 generates the magnetic field and stops the generation of the magnetic field. By doing this, even when the refrigerator is operated during the exploration of the target structure 12, noise superimposed on the detection result of the magnetic sensor part 210 can be reduced.

At least a part of the exploration system 10 according to the present embodiment is a computer or the like, for example. The computer functions as at least a part of the first control part 140, the first storage part 150, the interface part 180, the second control part 250, the second storage part 260, the communication part 270, and the monitor device 300 according to the present embodiment by executing programs, for example.

The computer includes a processor such as a central processing unit (CPU), and functions as at least a part of the first control part 140, the first storage part 150, the interface part 180, the second control part 250, the second storage part 260, and the communication part 270 by executing programs stored in the first storage part 150 and/or the second storage part 260. The computer may further include a graphics processing unit (GPS) or the like.

According to the present disclosure, it is possible to apply a wireless LAN of the existing standards, such as Wi-Fi, to the measurement using a magnetic field sensor of high sensitivity. When performing a measurement of the magnetic field while repeating the movement and installation of the magnetic field sensor apparatus outdoors for resource exploration or the like, it is possible to install the wireless LAN apparatus near the magnetic field sensor, and therefore the operating efficiency of the measurement improves.

The present disclosure is explained on the basis of the exemplary embodiments. The technical scope of the present disclosure is not limited to the scope explained in the above embodiments and it is possible to make various changes and modifications within the scope of the disclosure. For example, the specific embodiments of the distribution and integration of the apparatus are not limited to the above embodiments, all or part thereof, can be configured with any unit which is functionally or physically dispersed or integrated. Further, new exemplary embodiments generated by arbitrary combinations of them are included in the exemplary embodiments. Further, effects of the new exemplary embodiments brought by the combinations also have the effects of the original exemplary embodiments.

What is claimed is:

1. An exploration system that electromagnetically explores a target structure, comprising:
a magnetic field generation apparatus that generates a magnetic field toward the target structure; and
a magnetic field detection apparatus that detects a magnetic field that propagated from the target structure, the propagated magnetic field being generated due to the magnetic field generated by the magnetic field generation apparatus, wherein
the magnetic field detection apparatus has a communication part that transmits information of the detected magnetic field to an external device in synchronization with a timing at which the magnetic field generation apparatus generates the magnetic field and a timing at which the generation of the magnetic field is stopped.

2. The exploration system according to claim 1, wherein the communication part transmits the information of the detected magnetic field to the external device during a period when the magnetic field generation apparatus is generating the magnetic field.

3. The exploration system according to claim 1, wherein the communication part stops transmitting the information of the detected magnetic field at a timing prior to the timing at which the magnetic field generation apparatus stops the generation of the magnetic field.

4. The exploration system according to claim 1, wherein the communication part stops transmitting the information of the detected magnetic field until a predetermined time passes from the timing at which the magnetic field generation apparatus stops the generation of the magnetic field.

5. The exploration system according to claim 1, wherein the communication part starts transmitting the information of the detected magnetic field after a timing at which the magnetic field generation apparatus starts the generation of the magnetic field.

6. The exploration system according to claim 1, wherein the magnetic field generation apparatus repeats the generation of the magnetic field and the stop of the generation of the magnetic field at a predetermined cycle, and
the communication part repeats the transmission of the information of the detected magnetic field in the same cycle as the predetermined cycle.

7. The exploration system according to claim 1, wherein
the magnetic field generation apparatus has
a first acquisition part that acquires first time information,
a current generation part that generates current,
a magnetic field generation part that generates a magnetic field on the basis of the current generated by the current generation part,
a switching part that switches whether to supply the current generated by the current generation part to the magnetic field generating part, and
a first control part that controls a switching timing of the switching part on the basis of the first time information acquired by the first acquisition part,
the magnetic field detection apparatus further has
a second acquisition part that acquires second time information synchronized with the first time information, and
the communication part that transmits the information of the detected magnetic field to the external device at a timing based on the second time information.

8. The exploration system according to claim 7, wherein the first control part controls the switching part to, every hour on the hour, stop supplying current from the current generation part to the magnetic field generation apparatus.

9. The exploration system according to claim 8, wherein the switching part further switches a direction of current supplied to the magnetic field generation apparatus,
the first control part controls the switching part to sequentially switch among four states at constant time intervals, the four states being (i) a first period in which the current is supplied in a first direction, (ii) a second period in which the supply of the current in the first direction is stopped, (iii) a third period in which the current is supplied in a second direction opposite to the first direction, and (iv) a fourth period in which the supply of the current in the second direction is stopped, and
the communication part transmits the information of the detected magnetic field in a period included in the first period and the third period to the external device.

10. The exploration system according to claim 9, wherein the first period, the second period, the third period, and the fourth period are each defined in advance as a time interval during which a secondary magnetic field propagates underground and becomes attenuated sufficiently below a detection limit to an extent that a detection of a next secondary magnetic field will not be affected, the secondary magnetic field being generated due to initiation and stoppage of generating a primary magnetic field with the magnetic field generation apparatus.

11. An exploration method that electromagnetically explores a target structure, comprising:
generating a magnetic field toward the target structure with a magnetic field generation apparatus;
detecting a magnetic field that propagated from the target structure, the propagated magnetic field being generated due to the magnetic field generated by the magnetic field generation apparatus; and
transmitting information of the detected magnetic field to an external device in synchronization with a timing at which the magnetic field generation apparatus generates the magnetic field and a timing at which the generation of the magnetic field is stopped.

12. A magnetic detection apparatus having:
an acquisition part that acquires time information;
a magnetic sensor part that detects a magnetic field that propagated from the target structure, the propagated magnetic field being generated due to the magnetic field generated by the magnetic field generation apparatus; and
a communication part that transmits information of the magnetic field detected by the magnetic sensor part to an external device in synchronization with the time information acquired by the acquisition part.
